(19) United States
(12) Patent Application Publication
(10) Pub. No.: US 2012/0048190 A1
(43) Pub. Date: Mar. 1, 2012

(54) SYSTEM AND METHOD FOR ULTRASONIC FOCUSED PRINTING

(76) Inventors: Reinhold F. Wirth, Sandia Park, NM (US); John W. Elling, Santa Fe, NM (US)

(21) Appl. No.: 13/223,076

(22) Filed: Aug. 31, 2011

Related U.S. Application Data
(60) Provisional application No. 61/378,918, filed on Aug. 31, 2010.

(51) Int. Cl. B05C 11/00

(52) U.S. Cl. 118/612

(57) ABSTRACT

Printing of conductive layers on and/or in semiconductor materials using acoustic focusing to create a standing half-wave sound wave across a capillary. In response to the acoustic pressure, particles denser than the fluid in the capillary are driven to the node in the center of the capillary to concentrate metal particles within an organic solvent flowing through the capillary. Depositing the focused flow on a surface and/or substrate creates a line of metal particles that can be subsequently treated to create a conductive line. The concentrated metal particles are arranged in a stream of ink and subsequently deposited on a surface, creating a long pile of metal particles that are subsequently treated to form a conductive line for use in photovoltaic arrays.

### CROSS-REFERENCE TO RELATED APPLICATIONS

This application claims the benefit of U.S. Provisional Patent Application Ser. No. 61/378,918 entitled “SYSTEM AND METHOD FOR ULTRASONIC FOCUSED PRINTING” which was filed Aug. 31, 2010. The entirety of the aforementioned application is herein incorporated by reference.

### BACKGROUND AND SUMMARY

The present invention relates generally to the design and manufacture of photovoltaic cells for use in renewable solar energy applications and other printed electronics. More specifically, the present invention relates to one or more systems, computer program products and/or methods for the printing of conductive layers on and/or in semiconductor materials for the capture of solar energy.

One aspect of the system of the preferred embodiment includes acoustic focusing to create a standing half-wave sound wave across a capillary. In response to the acoustic pressure, particles denser than the fluid in the capillary are driven to the node in the center of the capillary, that is, to concentrate metal particles within an organic solvent flowing through the capillary. Depositing the focused flow on a surface and/or substrate will create a line of metal particles that can be subsequently treated to create a conductive line. The concentrated metal particles can be arranged in a stream of ink and subsequently deposited on a surface, creating a long pile of metal particles that can be subsequently treated (for example, by heat in order to melt the particles together) to form a conductive line for use in photovoltaic arrays.

Other aspects and features of the present invention are described in detail with reference to the following drawings.

### BRIEF DESCRIPTION OF THE DRAWINGS

FIG. 1 is a schematic block diagram of a system according to a preferred embodiment of the present invention.

FIG. 2 is a flowchart depicting a method according to a preferred embodiment of the present invention.

### DETAILED DESCRIPTION

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.), or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), and optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated date signal with computer readable program code embodied thereon, for example, in baseband or as part of a carrier wave. Such a propagated signal may take any variety of forms, including, but not limited to, electromagnetic, optical, or any suitable combination thereof. A computer readable signal medium may be any computer readable medium that is not a computer readable storage medium and that can communicate, propagate, or transport a program for use by or in conjunction with an instruction execution system, apparatus, or device.

Program code embodied on a computer readable medium may be transmitted using any appropriate medium, including but not limited to wireless, wireline, optical fiber cable, RF and the like, or any suitable combination of the foregoing.

Computer program code for carrying out operations for aspects of the present invention may be written in any combination of one or more programming languages, including an object oriented programming language such as Java, Smalltalk, C++ or the like or conventional procedural programming languages, such as the “C” programming language or similar programming languages. The programming code may execute entirely on the user's computer, partly on the user's computer, as a stand-alone software package, partly on the user's computer and partly on a remote computer or entirely on a remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer-implemented process such that the instructions which execute on the computer or other programmable apparatus provide processes for implementing the functions/acts specified in the flowchart and/or block diagram block or blocks. As used herein, a “terminal” should be understood to be any one of a general purpose computer, as for example a personal computer or a laptop computer, a special purpose computer such as a server, or a smart phone, soft phone, personal digital assistant or any other machine adapted for executing programmable instructions in accordance with the description thereof set forth above.

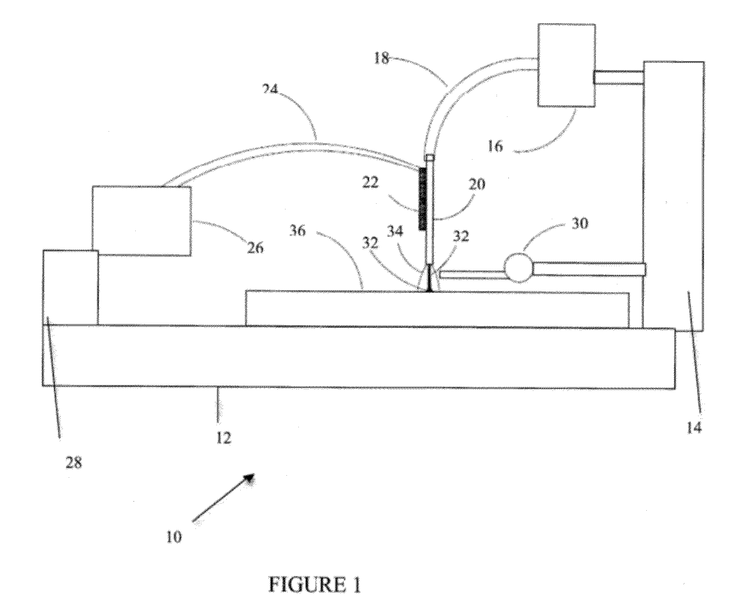

FIG. 1 illustrates a system 10 according to a preferred embodiment of the present invention. As shown therein, system 10 of the preferred embodiment can include a platform 12, which can optionally include vertical portions 14, 28 upon which other components of system 10 of the preferred embodiment can be mounted. A capillary tube 20 can be used for acoustic focusing of a metal particle 34 in a carrier solution 32 or suspension. In one variation of system 10 of the preferred embodiment, the metal particle in solution can include silver particles suspended in ethanol, ethylene glycol, or any other suitable organic carrier fluid. Other suitable conductive particles can also be used in conjunction with or in lieu of silver.

As shown in FIG. 1, the metal particles can be held in a reservoir 16 that is in fluid communication with capillary tube 20, such as through a feeder tube 18. Capillary tube 20 can be any suitable length, such as for example, on the order of 75 millimeters with various internal diameters, such as for example on the order of 200 microns. Capillary tube 20 can be affixed, adjacent to, or in acoustic communication with a piezo type material 22 or any other suitable material for inducing acoustic focusing of a material within capillary tube 20. in one example embodiment, piezo material 22 can be approximately 15 millimeters wide and close to the axial length of capillary tube 20.

In one variation of system 10 of the preferred embodiment, capillary tube 20 is affixed to piezo material 22 in such a manner as to allow the oscillations at an appropriate frequency created by an electrical connection to a wave form frequency generator to selected particles 34 into the middle of carrier fluid 32 and capillary tube 20. As shown in FIG. 1, system 10 of the preferred embodiment can include a controller 26 that is in communication with piezo material 22. As shown in FIG. 1, controller 26 is connected to piezo material 22 via a wire 24, although wireless communications are equally well suited for the present invention. Controller 26 can be configured to cause piezo material 22 to oscillate at predetermined frequencies and for predetermined intervals in order to deposit the metal particles on substrate 36 according to the user's design.

In another variation of system 10 of the preferred embodiment, capillary tube 20 is movably connected to platform 12 such that the former can move with respect thereto in response to a predetermined set of directions. In particular, capillary tube 20 can be translated in virtually any direction, i.e., along X, Y, and Z axes, such that the selected particles can be deposited at predetermined positions and depths in or on a substrate 36. Movement of capillary tube 20 relative to the platform can be controlled and actuated by controller 26 according to the specific layout and print design set forth by the user. Alternatively, capillary tube 20 can be fixed in space along one or more axes relative to platform 12, and platform 12 can be configured to move substrate 36 relative to capillary tube 20, thus permitting the relative motion between capillary tube 20 and substrate 36.

In another variation of system 10 of the preferred embodiment shown in FIG. 1, as metal particles 34 exit capillary tube 20 in a nearly columnar fashion they will be deposited at a stand-off distance from substrate 36 to prevent capillary contact with substrate 36. However, capillary tube 20 and substrate 36 can be located substantially close enough to form a slight meniscus between substrate 36 and capillary tube 20 to allow metal particles 34 and carrier liquid 32 to be uniformly dispensed. The dispensing may be started and stopped at any desirable position through applying pressure or vacuum or some mechanical means, such as for example a shutter mechanism 30.

in another variation of system 10 of the preferred embodiment, piezo material 22 can be configured as a rectangular piezo ceramic affixed and an oscillating circuit that drives piezo material 22 at the desired frequency. Furthermore, capillary tube 20 can be substantially polished on the inside diameter to allow undisturbed flow of metal particles 34 and carrier fluid 32. Capillary tube 20 can be connected to piezo material 22 by any suitable means, including for example by glue or other adhesive in such a fashion as to allow all the energy from oscillating piezo material 22 to be transferred to capillary tube 20 to focus the denser material, i.e., metal particles 34, to the axial center of capillary tube 20.

In another variation of system 10 of the preferred embodiment, piezo material 22 can include a silver coating on one or more surfaces in order to make an electrical connection to an oscillating drive circuit. The electronic drive circuit can be adjustable (manually, by controller 26, or through a feed-back loop) so that the correct frequency can be applied to piezo material 22 in order to generate the acoustic wave. Alternatively, the drive circuit can detect the optimum frequency and track any changes allowing the frequency to change as the density, viscosity, and/or temperature of the metal particle solution in the capillary changes.

In another variation of system 10 of the preferred embodiment, system 10 can include one or more capillary tubes 20 that are in acoustic communication with one or more piezo materials 22 disposed on or adjacent thereto as set forth above. Similarly, each of the one or more capillary tubes 22 can be fed by one or more feeder tubes 18 connected to one or more reservoirs 16. In particular, system 10 of the preferred embodiment can be configured as an array of capillary tubes 22 configured for disposing multiple lines of metallic particles 34 on one or more substrates 36 in a substantially simultaneous fashion. In this manner, array of capillary tubes 22 can function in unison to line a larger surface area of substrate(s) 36 subject to the patterns and instructions set forth by controller(s) 26.

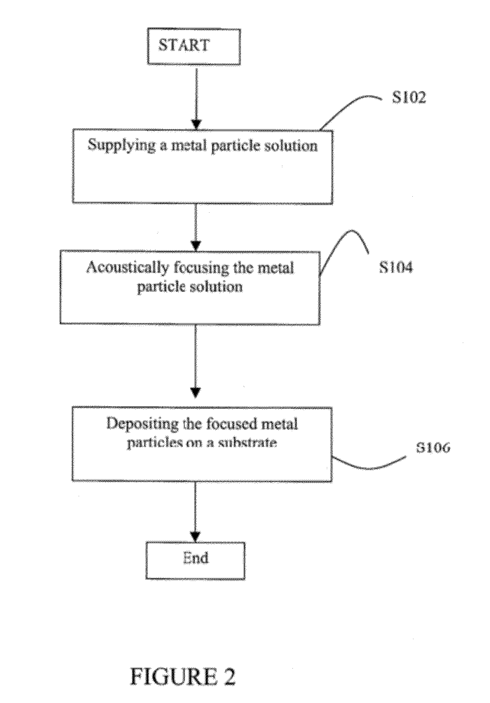

FIG. 2 is a flowchart depicting a method of depositing a metal particle on a substrate according to a preferred embodiment of the present invention. As shown therein, step S102 of the method of the preferred embodiment recites supplying a metal particle solution, such as for example silver particles disposed in ethanol or ethylene glycol as noted above. Step S104 of the method of the preferred embodiment recites acoustically focusing the metal particle solution. Step S106 of the method of the preferred embodiment recites depositing the focused metal particles on a substrate.

Each of the steps of the method of the preferred embodiment can be performed by the system of the preferred embodiment and variations and alternatives thereof described herein. Moreover, each of the steps of the method of the preferred embodiment can be controlled entirely or in part by a controller as described herein. As noted above, the method of the preferred embodiment can also be performed in whole or in part by an array of capillary tubes, thereby permitting the substantially simultaneous deposition of the metal particles into predetermined lines on the substrate(s). The controller can include one or more computer readable media for performing each of the foregoing steps in response to computer executable instructions.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block might occur out of the order noted in the Figures. For example, two blocks shown in succession may, in fact, be executed substantially concurrently, or the blocks may sometimes be executed In the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular terms “a”, “an”, and “the” are intended to include the plural forms as well, unless the context clearly indicates otherwise. It will be further understood that the terms “comprises” and/or “comprising,” when used in this specification, specify the presence of the stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements and specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical applications, and to enable others of ordinary skill in the art to understand the invention for various embodiments with various modifications as are suited to the particular use contemplated.

What is claimed is:

1. A system for printing conductive layers comprising:
means for acoustic focusing to create a standing half-wave sound wave across a capillary;
means for driving metal particles denser than the fluid in the capillary to a node in a center of the capillary via acoustic pressure from the acoustic focusing;
means for concentrating the flow metal particles within an organic solvent flowing through the capillary; and
means for depositing the concentrated flow on a surface and/or substrate to create a line of metal particles.
